(19) United States
(12) Patent Application Publication
(10) Pub. No.: US 2026/0123132 A1
(43) Pub. Date: Apr. 30, 2026

(54) DISPLAY DEVICE AND METHOD OF FABRICATING THE SAME

(71) Applicant: LG Display Co., Ltd., Seoul (KR)

(72) Inventors: TaeYoon KIM, Seoul (KR); HyeSun JUNG, Seoul (KR); BungGoo KIM, Paju-si (KR); HyoungHo AHN, Paju-si (KR); HeeWon LEE, Paju-si (KR); JunYoung JO, Paju-si (KR)

(73) Assignee: LG Display Co., Ltd., Seoul (KR)

(21) Appl. No.: 19/314,937

(22) Filed: Aug. 29, 2025

(30) Foreign Application Priority Data
Oct. 25, 2024 (KR) 10-2024-0147664

(51) Int. Cl. H10H 29/37; H10H 29/01

(52) U.S. Cl. CPC H10H 29/37; H10H 29/012

(57) ABSTRACT

A display device and a method of fabricating the display device are discussed. The display device can include a substrate, an active area having a plurality of pixels on the substrate, a plurality of insulating layers disposed in the active area, a first bank and a second bank disposed on the plurality of insulating layers, a first electrode disposed on the first bank and the second bank, at least one micro light emitting diode (LED) disposed on the first bank and the second bank, a first optical layer enclosing the first bank, the second bank, and a part of the at least one micro LED, a connection electrode disposed on the first bank, and a second electrode disposed on a top surface and a side surface of the first optical layer and connected to the connection electrode.

### CROSS-REFERENCE TO RELATED APPLICATIONS

This application claims priority to Korean Patent Application No. 10-2024-0147664 filed in the Republic of Korea on Oct. 25, 2024, the entire disclosure of which is hereby expressly incorporated by reference into the present application.

### BACKGROUND

### Field

The present disclosure relates to a light emitting diode (LED) display device and a method of fabricating the same, and more particularly, to a micro LED display device and a method of fabricating the same, where when a second electrode is connected to a connection electrode, splitting or disconnection of an electrode due to the connection between the electrodes is improved.

### Description of the Related Art

Recently, as display devices become larger, the demand for flat display elements that occupy a less space is increasing and the technology of flat panel display devices, such as liquid crystal display (LCD) devices or organic electroluminescent display (OLED) devices including organic light emitting diodes (OLED), is rapidly advancing.

In order to overcome the limitations of the LCD device and/or the OLED device as described above, an LED display device which uses a light emitting diode as a light emitting element is proposed. For the LED display device, a small-sized LED, such as a mini-LED, or an ultra-small sized LED, such as a micro-LED, can be used.

Such an LED display device is a display device in which a mini or micro unit of ultra-small sized LED is disposed in each sub pixel to implement images and has great advantages in terms of low power consumption and reduction in size.

In an LED with a vertical structure in which a cathode above the LED is connected to a second electrode and an anode below the LED is connected to a first electrode, the second electrode is disposed above the LED to electrically connect a pixel driving circuit of the substrate and the cathode of the LED. The LED and an insulating layer are disposed on the pixel driving circuit of the substrate and a contact hole of the insulating layer can be formed to electrically connect the second electrode and the pixel driving circuit.

When the second electrode is formed in the contact hole to be connected to the pixel driving circuit below the contact hole, the second electrode can be cracked to be split or broken depending on the depth of the contact hole.

Therefore, suppressing the crack of the second electrode is needed.

### SUMMARY OF THE DISCLOSURE

The present disclosure is provided to solve or address the above-described problems and other limitations associated with the related art.

An object of the present disclosure is to provide a display device with a structure which suppresses or prevents a crack that can be caused when the second electrode connected to an upper portion of the LED with a vertical structure is connected to the pixel driving circuit on the substrate, and to provide a fabricating method of the display device.

Objects of the present disclosure are not limited to the above-mentioned objects, and other objects, which are not mentioned above, can be clearly understood by those skilled in the art from the following descriptions.

According to an embodiment of the present disclosure, a display device includes a substrate, an active area having a plurality of pixels on the substrate, a plurality of insulating layers disposed in the active area, a first bank and a second bank disposed on the plurality of insulating layers, a first electrode disposed on the first bank and the second bank, at least one micro LED disposed on the first bank and the second bank, a first optical layer enclosing the first bank, the second bank, and a part of the at least one micro LED, a connection electrode disposed on the first bank, and a second electrode disposed on a top surface and a side surface of the first optical layer and connected to the connection electrode.

According to an embodiment of the present disclosure, a method of fabricating a display device includes forming a pixel driving circuit and a plurality of pixels on a substrate, forming a plurality of insulating layers on the pixel driving circuit, forming a first bank and a second bank on the plurality of insulating layers, forming a connection electrode in the first bank, placing at least one micro LED on the first bank and the second bank, forming a first optical layer which encloses the first bank, the second bank, and the at least one micro LED, and placing a second electrode on the first optical layer, wherein the second electrode is connected to the connection electrode on the first bank and the connection electrode and the second electrode is formed to extend along a side surface of the first bank.

Other detailed matters of the example embodiments of the present disclosure are included in the detailed description and the drawings.

According to aspects of the present disclosure, a display device which has a long lifespan and is driven at a low power by suppressing or preventing cracks of the second electrode of the LED display device is provided.

According to aspects of the present disclosure, a process for connecting the second electrode and the connection electrode is minimized to save a process cost.

The effects according to the present disclosure are not limited to the contents exemplified above, and further various effects are included in the present disclosure.

### BRIEF DESCRIPTION OF THE DRAWINGS

The above and other aspects, features and other advantages of the present disclosure will be more clearly understood from the following detailed description taken in conjunction with the accompanying drawings, in which:

FIG. 1 is an exploded perspective view of a display device according to an example embodiment of the present disclosure;

FIG. 2 is a plan view of a display device according to an example embodiment of the present disclosure;

FIG. 3 is a plan view of a display device enlarging an area 3 of FIG. 2;

FIG. 4 is a cross-sectional view taken along line A-A′ of FIG. 3 according to an example embodiment of the present disclosure;

FIG. 5 is a plan view of a display device according to an example embodiment of the present disclosure;

FIG. 6 is an enlarged view of a light emitting diode according to an example embodiment of the present disclosure;

FIG. 7A is a cross-sectional view taken along line a-a′ of FIG. 5 according to an example embodiment of the present disclosure;

FIG. 7B is a cross-sectional view taken along line b-b′ of FIG. 5 according to an example embodiment of the present disclosure;

FIG. 7C is a cross-sectional view taken along line c-c′ of FIG. 5 according to an example embodiment of the present disclosure;

FIG. 8 is a plan view of a display device according to another example embodiment of the present disclosure;

FIG. 9A is a cross-sectional view taken along line a1-a1′ of FIG. 8 according to another example embodiment of the present disclosure;

FIG. 9B is a cross-sectional view taken along line b1-b1′ of FIG. 8 according to another example embodiment of the present disclosure; and

FIG. 10 is a plan view illustrating a display device according to an example embodiment of the present disclosure.

### DETAILED DESCRIPTION OF THE EMBODIMENTS

Advantages and characteristics of the present disclosure and a method of achieving the advantages and characteristics will be clear by referring to example embodiments described below in detail together with the accompanying drawings. However, the present disclosure is not limited to the example embodiments disclosed herein but will be implemented in various forms. The example embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the example embodiments of the present disclosure are merely examples, and the present disclosure is not limited thereto. Like reference numerals generally denote like elements throughout the specification. Further, in the following description of the present disclosure, a detailed explanation of known related technologies can be omitted to avoid unnecessarily obscuring the subject matter of the present disclosure. The terms such as “including,” “having,” and “comprising” used herein are generally intended to allow other components to be added unless the terms are used with the term “only”. Any references to singular can include plural unless expressly stated otherwise.

Components are interpreted to include an ordinary error range even if not expressly stated.

When the position relation between two parts is described using the terms such as “on”, “above”, “below”, and “next”, one or more parts can be positioned between the two parts unless the terms are used with the term “immediately” or “directly”.

When explaining temporal relationships, terms such as “after,” “following,” “subsequent to,” or “before,” etc., can include non-consecutive cases unless terms like “immediately” or “directly” are used.

Terms such as “first,” “second,” etc. are used to describe various components, but these components are not limited by these terms. These terms are merely used to distinguish one component from another. Therefore, a first component mentioned herein could be a second component within the technical scope of the present disclosure.

In describing the components of the present disclosure, terms such as first, second, A, B, (a), or (b) can be used. These terms are only intended to distinguish that one component from other components, and the nature, order, sequence, or number of the respective component is not limited by these terms.

When a component is described as being “connected,” “coupled,” “joined,” or “attached” to another component, it should be understood that the component can be directly connected, coupled, joined, or attached to the other component, but unless explicitly specified otherwise, it can also be indirectly connected, coupled, joined, or attached with another component intervening between each component.

When a component or layer is described as being “in contact with” or “overlapping” another component or layer, the component or layer can directly contact or overlap the other component or layer, but unless explicitly specified otherwise, it should be understood that it can also indirectly contact or overlap with another component intervening between each component.

The term “at least one” should be understood to include all combinations of one or more of the associated components. For example, “at least one of first, second, and third components” means not only the first, second, or third component, but also includes all combinations of two or more components from among the first, second, and third components.

The terms such as “first direction”, “second direction”, “third direction”, “X-axis direction”, “Y-axis direction”, and “Z-axis direction” should not be interpreted solely as geometric relationships perpendicular to each other, but can indicate broader directionality within the range where the configuration of the present disclosure can function. Further, the term “can” fully encompasses all the meanings and coverages of the term “may” and vice versa.

The features of various embodiments in the present disclosure can be partially or wholly combined or associated with each other, various technical interlocking and operations are possible, and each embodiment can be implemented independently of each other or can be implemented together in an associated relationship.

Hereinafter, a display device according to example embodiments of the present disclosure will be described in detail with reference to accompanying drawings. All the components of each display device/apparatus according to all embodiments of the present disclosure are operatively coupled and configured.

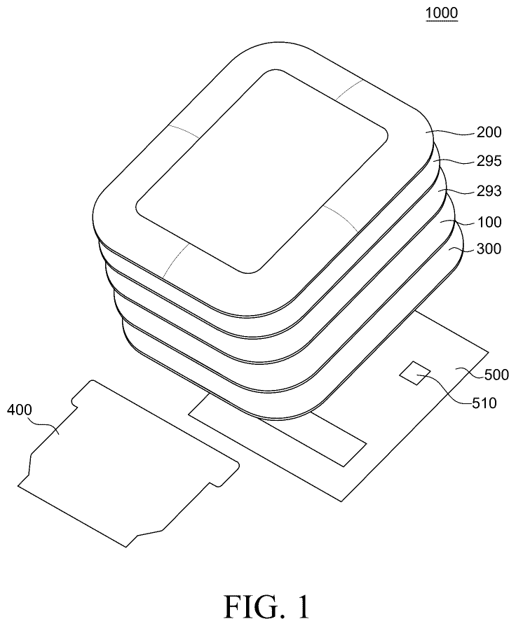

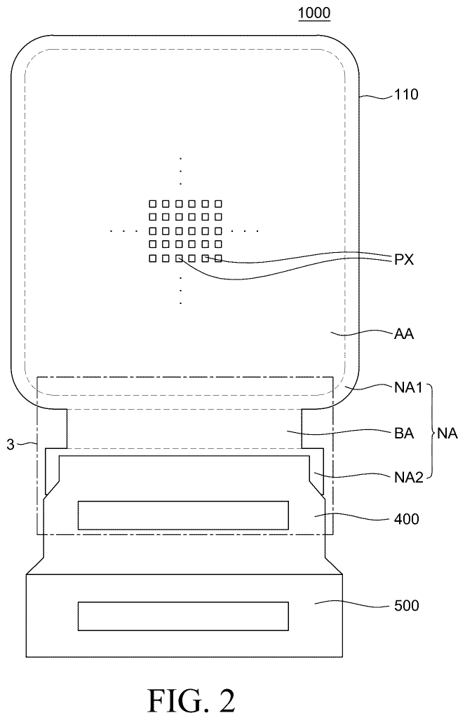

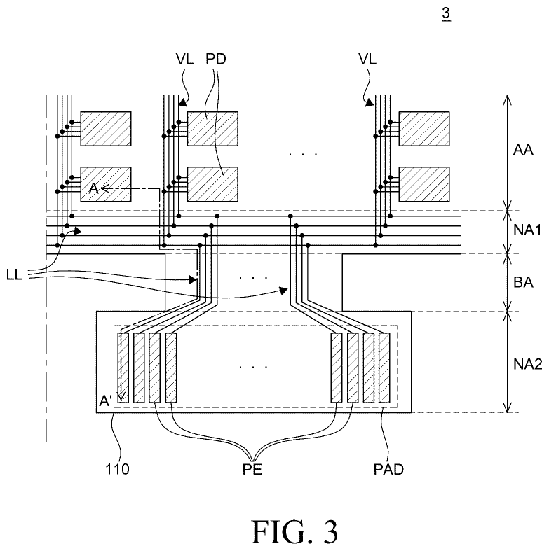

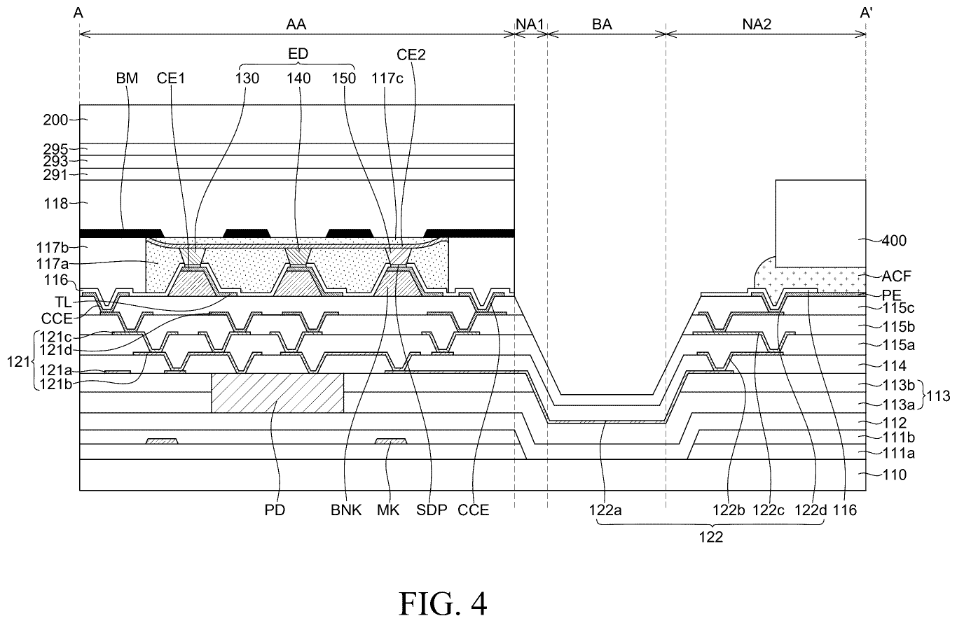

FIG. 1 is a perspective view illustrating a display device according to an example embodiment of the present disclosure. FIG. 2 is a plan view of the display device according to the example embodiment of the present disclosure. FIG. 3 is an enlarged view of the display device according to the example embodiment of the present disclosure and FIG. 4 is a cross-sectional view taken along line A-A′ of FIG. 3 according to the example embodiment of the present disclosure.

Referring to FIGS. 1 to 4, a display device 1000 according to the example embodiment of the present disclosure can include a display panel 100, a polarization layer 293, an adhesive layer 295, a cover member 200, a support substrate 300, a flexible circuit board 400, and a printed circuit board 500. The cover member 200 can be attached to the display panel 100 using the adhesive layer 295. The adhesive layer 295 can be also disposed between the display panel 100 and the polarization layer 293 or between the display panel 100 and the support substrate 300.

The adhesive layer 295 can include an optically clear adhesive (OCA), an optically clear resin (OCR), or a pressure sensitive adhesive (PSA), but the example embodiments of the present disclosure are not limited thereto.

For example, the display panel 100 of the display device 1000 can include a substrate 110. The substrate 110 can be a member which supports other components of the display device 1000. The substrate 110 is formed of an insulating material. For example, the substrate 110 can be formed of glass or resin. Further, the substrate 110 can also be formed of a material having a flexibility. For example, the substrate 110 can be formed of a plastic material having flexibility, such as polyimide (PI), but the example embodiments of the present disclosure are not limited thereto.

The display panel 100 can implement information, videos, and/or images which are provided to users. For example, the display panel 100 can include an active area AA and a non-active area NA. For example, the substrate 110 includes an active area AA and a non-active area NA. However, the active area AA and the non-active area NA are not mentioned to be limited to the substrate 110, but can be mentioned for the entire display device 1000.

The active area AA is an area where images are displayed. The active area AA can include a plurality of pixels PX. Each of the plurality of pixels PX can be configured by a plurality of sub pixels. A plurality of micro light emitting diodes (LEDs) can be disposed in each of the plurality of sub pixels. The micro LEDs can also be referred to herein as micro light emitting elements.

The plurality of micro LEDs can be configured in different manners depending on the type of the display device 1000.

The non-active area NA is an area where no image is displayed. In the non-active area NA, various wiring lines and circuits for driving the plurality of pixels PX of the active area AA can be disposed. For example, in the non-active area NA, various wiring lines and driving circuits can be mounted and a pad unit PAD to which an integrated circuit and a printed circuit are connected can be disposed, but the example embodiments of the present disclosure are not limited thereto.

For example, the driving circuit can be a data driving circuit and/or a gate driving circuit, but the example embodiments of the present disclosure are not limited thereto. Wiring lines through which a control signal for controlling driving circuits is supplied can be disposed. For example, the control signal can include various timing signals including a clock signal, an input data enable signal, and synchronization signals, but the example embodiments of the present disclosure are not limited thereto. The control signal can be received through the pad unit PAD. For example, in the non-active area NA, link lines LL can be disposed to transmit signals. For example, driving components, such as the flexible circuit board 400 and the printed circuit board 500, can be connected to the pad unit PAD.

According to aspects of the present disclosure, the non-active area NA can include a first non-active area NA1, a bending area BA, and a second non-active area NA2. For example, the first non-active area NA1 can be an area which encloses at least a part of the active area AA. The bending area BA is an area extending from at least one side, among a plurality of sides of the first non-active area NA1 and can be a bendable area. The second non-active area NA2 is an area extending from the bending area BA and the pad unit PAD can be disposed therein. For example, the bending area BA is in a bent state and the other areas of the substrate 110 excluding the bending area BA can be in a flat state. In this case, as the bending area BA is bent, the second non-active area NA2 can be located on a rear surface of the active area AA, but the example embodiments of the present disclosure are not limited thereto.

The active area AA of the substrate 110 or the display device 1000 can be configured with various shapes depending on a design of the display device 1000. For example, the active area AA can be configured with a rectangular shape formed with four rounded corners, but the example embodiments of the present disclosure are not limited thereto. As another example, the active area AA can be configured with a rectangular shape formed with four right-angled corners or a circular shape, but the example embodiments of the present disclosure are not limited thereto.

According to aspects of the present disclosure, a width of the second non-active area NA2 in which the plurality of pad electrodes PE is disposed can be larger than a width of the bending area BA in which only a plurality of link lines LL is disposed. Further, a width of the active area AA in which the plurality of sub pixels is disposed can be larger than a width of the bending area BA in which only a plurality of link lines LL is disposed. Even though in the drawing, it is illustrated that the width of the bending area BA is smaller than a width of the other area of the substrate 110, the shape of the substrate 110 including the bending area BA is illustrative and the example embodiments of the present disclosure are not limited thereto.

Referring to FIG. 4, a plurality of pixel driving circuits PD can be disposed in the active area AA. The plurality of pixel driving circuits PD can be circuits for driving micro LEDs of the plurality of sub pixels. Each of the plurality of pixel driving circuits PD includes a plurality of transistors including a driving transistor and a storage capacitor and supplies a control signal, a power, and a driving current to the micro LEDs of the plurality of sub pixels to control an emission operation of the plurality of micro LEDs. For example, the pixel driving circuit PD can include a power line and a signal line for controlling emission on/off of the micro LED and/or an emission time. For example, the plurality of pixel driving circuits PD can be driving drives manufactured using a metal-oxide-silicon field effect transistor (MOSFET) fabricating process on a semiconductor substrate, but the example embodiments of the present disclosure are not limited thereto. The driving driver includes a plurality of pixel driving circuits PD and can drive a plurality of sub pixels.

Referring to FIG. 1 together, the flexible circuit board 400 and the printed circuit board 500 can be disposed below the display panel 100. The flexible circuit board 400 and the printed circuit board 500 can be disposed at least at one edge of the display panel 100, but the example embodiments of the present disclosure are not limited thereto.

A pad unit PAD including a plurality of pad electrodes PE can be disposed in the second non-active area NA2. In the pad unit PAD, a driving component including one or more flexible circuit boards (or flexible films) 400 and the printed circuit board 500 can be attached or bonded. The plurality of pad electrodes PE of the pad unit PAD is electrically connected to one or more flexible circuit boards (or flexible films) 400 and can transmit various signals (or powers) from the printed circuit board 500 and the flexible circuit board (or a flexible film) 400 to the plurality of pixel driving circuits PD of the active area AA.

The flexible circuit board (or flexible film) 400 can be a film on which various components are disposed on a base film having ductility. For example, driving ICs such as a gate driver IC or a data driver IC can be disposed in the flexible circuit board (or flexible film) 400, but the example embodiments of the present disclosure are not limited thereto.

Referring to FIGS. 1 to 3, the plurality of link lines LL can be disposed in the non-active area NA. The plurality of link lines LL can be wiring lines which transmit various signals from one or more flexible circuit boards (or flexible films) 400 and the printed circuit board 500 to the active area AA. The plurality of link lines LL extends from the plurality of pad electrodes PE of the second non-active area NA2 toward the bending area BA and the first non-active area NA1 to be electrically connected to the plurality of driving lines VL of the active area AA.

The plurality of driving lines VL is disposed in the active area AA to be electrically connected to each of the plurality of pixel driving circuits PD.

As the bending area BA is bent, a part of the plurality of link lines LL is bent together. A stress is concentrated in the bent part of the link line LL, which causes a crack on the link line LL. Accordingly, the plurality of link lines LL can be configured by a conductive material having excellent ductility to reduce the crack caused when the bending area BA is bent. For example, the plurality of link lines LL can be configured by a conductive material having excellent ductility, such as gold (Au), silver (Ag), or aluminum (Al), but the example embodiments of the present disclosure are not limited thereto. Further, the plurality of link lines LL can be configured by one of various conductive materials used for the active area AA. For example, the plurality of link lines LL can be configured by molybdenum (Mo), chrome (Cr), titanium (Ti), nickel (Ni), neodymium (Nd), copper (Cu), and an alloy of silver (Ag) and magnesium (Mg) or an alloy thereof, but the example embodiments of the present disclosure are not limited thereto. The plurality of link lines LL can be configured by a multi-layered structure including various conductive materials. For example, the plurality of link lines LL can be configured with a triple layered structure of titanium (Ti)/aluminum (Al)/titanium (Ti), but the example embodiments of the present disclosure are not limited thereto.

In the meantime, for the convenience of illustration, in FIG. 3, it is illustrated that a trimming line of A-A′ and a driving line VL and a link line LL do not overlap, but the trimming line A-A′ of FIG. 3 is provided to represent the same position as each of the adjacent driving line VL and link line LL.

Referring to FIG. 4, a first buffer layer 111a and a second buffer layer 111b can be disposed in the remaining area of the substrate 110 excluding the bending area BA.

The first buffer layer 111a and the second buffer layer 111b can be disposed in the active area AA, the first non-active area NA1, and the second non-active area NA2. The first buffer layer 111a and the second buffer layer 111b can reduce permeation of moisture or impurities through the substrate 110. The first buffer layer 111a and the second buffer layer 111b can be formed of an inorganic insulating material. For example, the first buffer layer 111a and the second buffer layer 111b can be configured by a single layer or multiple layers of silicon oxide (SiOx) or silicon nitride (SiNx), but the example embodiments of the present disclosure are not limited thereto.

For example, the first buffer layer 111a and the second buffer layer 111b on the bending area BA can be partially removed. A top surface of the substrate 110 located in the bending area BA can be exposed from the first buffer layer 111a and the second buffer layer 111b. The first buffer layer 111a and the second buffer layer 111b which are formed of an inorganic insulating material are removed from the bending area BA to minimize cracks of the first buffer layer 111a and the second buffer layer 111b which can be generated during the bending.

A plurality of alignment keys MK can be disposed between the first buffer layer 111a and the second buffer layer 111b. The plurality of alignment keys MK can be configured to identify a position of the pixel driving circuit PD during the fabricating process of the display device 1000. For example, the plurality of alignment keys MK can be configured to align a position of the pixel driving circuit PD which is transferred onto the adhesive layer 112. As another example, the plurality of alignment keys MK can be omitted.

The adhesive layer 112 can be disposed on the second buffer layer 111b. The adhesive layer 112 can be disposed in the active area AA, the first non-active area NA1, the bending area BA, and the second non-active area NA2. As another example, in the non-active area NA including the bending area BA, at least a part of the adhesive layer 112 can be removed. For example, the adhesive layer 112 can be formed of any one of adhesive polymer, epoxy resin, UV curable resin, polyimide based, acrylate based, urethane based, and polydimethylsiloxane (PDMS), but the example embodiments of the present disclosure are not limited thereto.

The pixel driving circuit PD can be disposed on the adhesive layer 112 in the active area AA. When the pixel driving circuit PD is implemented as a driving driver, the driving driver can be mounted on the adhesive layer 112 by the transfer process, but the example embodiments of the present disclosure are not limited thereto.

A first protection layer 113a and a second protection layer 113b can be disposed on top surfaces or side surfaces of the adhesive layer 112 and the pixel driving circuit PD. The first protection layer 113a and the second protection layer 113b can be disposed so as to enclose the side surface of the pixel driving circuit PD, but the example embodiments of the present disclosure are not limited thereto. For example, the second protection layer 113b can be disposed so as to cover at least a part of a top surface of the pixel driving circuit PD.

For example, at least one of the first protection layer 113a and the second protection layer 113b disposed on the bending area BA can be omitted. For example, the first protection layer 113a is entirely disposed in the active area AA and the non-active area NA and the second protection layer 113b can be partially disposed in the active area AA, the first non-active area NA1, and the second non-active area NA2. For example, a part of the second protection layer 113b in the bending area BA can be removed, but the example embodiments of the present disclosure are not limited thereto.

The first protection layer 113a and the second protection layer 113b can be configured by an organic insulating material, but the example embodiments of the present disclosure are not limited thereto. For example, the first protection layer 113a and the second protection layer 113b can be configured by a photo resist, polyimide (PI), or photo acrylic-based material, but the example embodiments of the present disclosure are not limited thereto. For example, the first protection layer 113a and the second protection layer 113b can be over coating layers or insulating layers, but the example embodiments of the present disclosure are not limited thereto.

According to aspects of the present disclosure, in the active area AA, the plurality of first connection lines 121 can be disposed on the second protection layer 113b. The plurality of first connection lines 121 can be wiring lines which electrically connect the pixel driving circuit PD to the other component. For example, the pixel driving circuit PD can be electrically connected to the plurality of signal lines TL and the plurality of connection electrodes CCE through the plurality of first connection lines 121. For example, the plurality of first connection lines 121 includes a 1-1-th connection line 121a, a 1-2-th connection line 121b, a 1-3-th connection line 121c, and a 1-4-th connection line 121d. The 1-1-th connection line 121a, the 1-2-th connection line 121b, the 1-3-th connection line 121c, and the 1-4-th connection line 121d are electrically connected through a contact hole formed in an insulating layer between connection lines, but the example embodiments of the present disclosure are not limited thereto. Each of the plurality of first connection lines 121 refers to a signal line disposed on the same layer and the plurality of first connection lines 121 can include signal lines to which different signals are applied.

For example, a third protection layer 114 can be disposed on the second protection layer 113b. The third protection layer 114 can be entirely disposed in the active area AA, and the non-active area NA.

In the bending area BA, the third protection layer 114 can cover a side surface of the second protection layer 113b and the top surface of the first protection layer 113a. The third protection layer 114 can be configured by an organic insulating material. For example, the third protection layer 114 can be configured by a photo resist, polyimide (PI), or photo acrylic-based material, but the example embodiments of the present disclosure are not limited thereto. For example, the first protection layer 113a, the second protection layer 113b, and the third protection layer 114 can be configured by the same material, but the example embodiments of the present disclosure are not limited thereto.

A plurality of 1-2-th connection lines 121b can be disposed on the third protection layer 114 and the first insulating layer 115a can be disposed on the plurality of 1-2-th connection lines 121b. The first insulating layer 115a can be entirely disposed in the active area AA and the non-active area NA, but the example embodiments of the present disclosure are not limited thereto. The first insulating layer 115a is configured by an organic insulating material, but the example embodiments of the present disclosure are not limited thereto. For example, the first insulating layer 115a can be configured by a photo resist, polyimide (PI), or photo acrylic-based material, but the example embodiments of the present disclosure are not limited thereto.

The plurality of 1-3-th connection lines 121c can be disposed on the first insulating layer 115a. The plurality of 1-3-th connection lines 121c can be electrically connected to the plurality of 1-2-th connection lines 121b. For example, the 1-3-th connection lines 121c can be electrically connected to the 1-2-th connection line 121b through a contact hole of the first insulating layer 115a.

The second insulating layer 115b can be disposed on the plurality of 1-3-th connection lines 121c. The second insulating layer 115b can be disposed in a remaining area excluding the bending area BA, but the example embodiments of the present disclosure are not limited thereto. The second insulating layer 115b can be disposed in the active area AA, the first non-active area NA1, and the second non-active area NA2, but the example embodiments of the present disclosure are not limited thereto. For example, a part of the second insulating layer 115b disposed in the bending area BA can be removed. The second insulating layer 115b is configured by an organic insulating material, but the example embodiments of the present disclosure are not limited thereto. For example, the second insulating layer 115b can be configured by a photo resist, polyimide (PI), or photo acrylic-based material, but the example embodiments of the present disclosure are not limited thereto.

The plurality of 1-4-th connection lines 121d can be disposed on the second insulating layer 115b. The plurality of 1-4-th connection lines 121d can be electrically connected to the plurality of 1-3-th connection lines 121c. For example, the 1-4-th connection lines 121d can be electrically connected to the 1-3-th connection line 121c through a contact hole of the second insulating layer 115b.

The third insulating layer 115c can be disposed on the 1-4-th connection lines 121d. The third insulating layer 115c can be disposed in a remaining area excluding the bending area BA, but the example embodiments of the present disclosure are not limited thereto. The third insulating layer 115c can be disposed in the active area AA, the first non-active area NA1, and the second non-active area NA2. A part of the third insulating layer 115c disposed in the bending area BA can be removed. The third insulating layer 115c is configured by an organic insulating material, but the example embodiments of the present disclosure are not limited thereto. For example, the third insulating layer 115c can be configured by a photo resist, polyimide (PI), or photo acrylic-based material, but the example embodiments of the present disclosure are not limited thereto.

A plurality of signal lines TL can be disposed on the third insulating layer 115c in the active area AA. A plurality of banks BNK can be disposed on the third insulating layer 115c in the active area AA. The plurality of signal lines TL can be disposed to extend to an area between the plurality of banks BNK. For example, the plurality of signal lines TL can be disposed to be adjacent to any one of the plurality of banks BNK.

According to the present disclosure, in the non-active area NA, the plurality of second connection lines 122 can be disposed on the second protection layer 113b. The plurality of second connection lines 122 can be wiring lines which transmit a signal transmitted from the flexible circuit board (or flexible film) 400 and the printed circuit board 500 (see FIG. 1) to the pad unit PAD to the pixel driving circuit PD of the active area AA. For example, the plurality of second connection lines 122 is electrically connected to the plurality of pad electrodes PE to be applied with a signal from the flexible circuit board (or flexible film) 400 and the printed circuit board 500.

For example, the plurality of second connection lines 122 extends toward the active area AA from the pad unit PAD to transmit a signal to the wiring line of the active area AA. In this case, the plurality of second connection lines 122 can serve as link lines LL. The plurality of second connection lines 122 can include a 2-1-th connection line 122a, a 2-2-th connection line 122b, a 2-3-th connection line 122c, and a 2-4-th connection line 122d. Accordingly, a signal from the flexible circuit board (or flexible film) 400 and the printed circuit board 500 can be transmitted to the 2-1-th connection line 122a through the 2-4-th connection line 122d, the 2-3-th connection line 122c, and the 2-2-th connection line 122b.

The plurality of first connection lines 121 and the plurality of second connection lines 122 can be formed of any one of a conductive material having excellent ductility or various conductive materials used for the active area AA.

For example, the plurality of first connection lines 121 and the plurality of second connection lines 122 can be configured by molybdenum (Mo), chrome (Cr), titanium (Ti), nickel (Ni), neodymium (Nd), copper (Cu), and an alloy of silver (Ag) and magnesium (Mg) or an alloy thereof, but the example embodiments of the present disclosure are not limited thereto.

The third insulating layer 115c can be disposed on the plurality of first connection lines 121 and the plurality of second connection lines 122.

In the bending area BA, the substrate 110 is bent so that the second non-active area NA2 at least partially overlaps the active area AA. In order to allow the substrate 110 to be bent, a layer in the bending area BA disposed on the substrate 110 can be minimized to suppress the crack. Therefore, in the bending area BA, the first buffer layer 111a, the second buffer layer 111b, the second protection layer 113b, the second insulating layer 115b or the third insulating layer 115c is not formed, but the example embodiments of the present disclosure are not limited thereto.

As mentioned above, a plurality of banks BNK can be disposed on the third insulating layer 115c in the active area AA. The plurality of banks BNK can be disposed so as to overlap each of the plurality of sub pixels. One or more micro LEDs (ED) which emit the same color light can be disposed above each of the plurality of banks BNK.

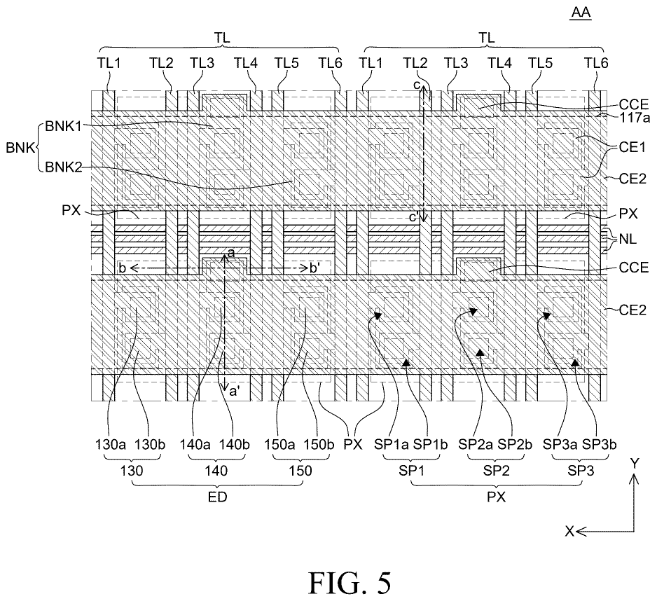

Referring to FIG. 5, the plurality of banks BNK can include a first bank BNK1 and a second bank BNK2. The first bank BNK1 and the second bank BNK2 can be formed by the same process and have a first width in the first direction X and a second width in the second direction Y. At this time, the second width of the first bank BNK1 can be larger than the second width of the second bank BNK2.

The plurality of banks BNK can be configured by a photo resist, polyimide (PI), or photo acrylic-based material, but the example embodiments of the present disclosure are not limited thereto.

A plurality of connection electrodes CCE can be disposed on the third insulating layer 115c in the active area AA. The plurality of connection electrodes CCE can supply a cathode voltage from the pixel driving circuit PD to the second electrode CE2.

The first electrode CE1 can be disposed on the bank BNK. For example, the first electrode CE1 can be disposed to extend toward the top of the bank BNK from the adjacent signal line TL. The first electrode CE1 can be disposed on the top surface of the bank BNK and the side surface of the bank BNK. For example, the first electrode CE1 can be disposed to extend from the signal line TL on the top surface of the third insulating layer 115c to the side surface of the bank BNK and the top surface of the bank BNK.

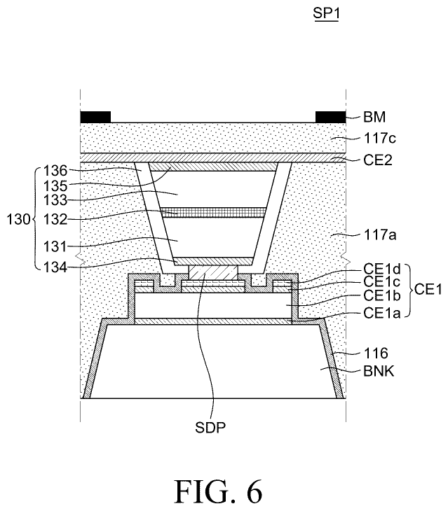

The first electrode CE1 can be configured by a plurality of conductive layers. For example, referring to FIG. 6, the first electrode CE1 can include a first conductive layer CE1a, a second conductive layer CE1b, a third conductive layer CE1c, and a fourth conductive layer CE1d, but the example embodiments of the present disclosure are not limited thereto.

Referring to FIG. 6, the first conductive layer CE1a can be disposed on the bank BNK. The second conductive layer CE1b can be disposed on the first conductive layer CE1a. The third conductive layer CE1c can be disposed on the second conductive layer CE1b. The fourth conductive layer CE1d can be disposed on the third conductive layer CE1c. For example, the first conductive layer CE1a, the second conductive layer CE1b, the third conductive layer CE1c, and the fourth conductive layer CE1d can be configured by titanium (Ti), molybdenum (Mo), aluminum (Al), or titanium (Ti) and indium tin oxide (ITO), but the example embodiments of the present disclosure are not limited thereto.

According to the present disclosure, in each of the plurality of sub pixels, a solder pattern SDP can be disposed on the first electrode CE1. The solder pattern SDP bonds the micro LED (ED) to the first electrode CE1 to electrically connect the first electrode CE1 and the micro LED (ED). For example, the first electrode CE1 and the anode electrode 134 of the micro LED (ED) can be electrically connected through eutectic bonding using the solder pattern SDP, but the example embodiments of the present disclosure are not limited thereto. For example, when the solder pattern SDP is configured by indium (In) and the anode electrode 134 of the micro LED (ED) is configured by gold (Au), during the transfer process of the micro LED (ED), heat and pressure are applied to bond the solder pattern SDP and the anode electrode 134. The micro LED (ED) can be bonded to the solder pattern SDP and the first electrode CE1 using the eutectic bonding without a separate adhesive material.

According to the present disclosure, the passivation layer 116 can be disposed on the plurality of signal lines TL, the plurality of first electrodes CE1, the plurality of connection electrodes CCE, and the third insulating layer 115c. For example, the passivation layer 116 can be disposed in the active area AA, the first non-active area NA1, and the second non-active area NA2. Apart of the passivation layer 116 disposed in the bending area BA can be removed. Apart of the passivation layer 116 which covers a plurality of pad electrodes PE in the second non-active area NA2 can be removed. The passivation layer 116 is disposed so as to cover the remaining area excluding an area in which the bending area BA, the plurality of pad electrodes PE, and the solder pattern SDP are disposed to reduce permeation of moisture or impurity introduced to the micro LED (ED) which is disposed above the insulating layers formed of an organic material. For example, the passivation layer 116 can be configured by a single layer or multiple layers of silicon oxide (SiOx) or silicon nitride (SiNx), but the example embodiments of the present disclosure are not limited thereto.

In each of the plurality of sub pixels, the micro LED (ED) can be disposed on the solder pattern SDP. A first micro LED 130 can be disposed in the first sub pixel SP1. A second micro LED 140 can be disposed in the second sub pixel SP2. A third micro LED 150 can be disposed in the third sub pixel SP3.

According to the present disclosure, in the active area AA, a first optical layer 117a which encloses the plurality of micro LEDs (ED) can be disposed. The first optical layer 117a can be continuously disposed in the plurality of pixels PX. For example, the first optical layer 117a can be disposed so as to cover the plurality of micro LEDs (ED) and the bank BNK in the area of the plurality of sub pixels. For example, the first optical layer 117a can cover the bank BNK, a part of the passivation layer 116 and between the plurality of micro LEDs (ED). The first optical layer 117a can be disposed or cover between the plurality of micro LEDs (ED) and between the plurality of banks BNK included in one pixel PX. For example, the first optical layer 117a extends in the first direction X and can be disposed to be spaced apart from each other in the second direction Y which intersects the first direction X. For example, the first optical layer 117a is disposed so as to enclose at least a part of side portions of the micro LED (ED) and the bank BNK between the passivation layer 116 and the second electrode CE2, but the example embodiments of the present disclosure are not limited thereto.

The first optical layer 117a includes an organic insulating material in which micro particles are dispersed, but the example embodiments of the present disclosure are not limited thereto. For example, the first optical layer 117a can be configured by siloxane in which micro metal particles, such as titanium dioxide (TiO₂) particles, are dispersed, but the example embodiments of the present disclosure are not limited thereto. Light from the plurality of micro LEDs (ED) is scattered by micro particles dispersed in the first optical layer 117a to be emitted to the outside of the display device 1000. Accordingly, the first optical layer 117a can improve extraction efficiency of light emitted from the plurality of micro LEDs (ED).

For example, the first optical layer 117a can be disposed in each of the plurality of pixels PX or disposed in some pixel PX disposed in the same row together, but the example embodiments of the present disclosure are not limited thereto. For example, the first optical layer 117a is disposed in each of the plurality of pixels PX or the plurality of pixels PX can share one first optical layer 117a. As another example, each of the plurality of sub pixels separately includes the first optical layer 117a, but the example embodiments of the present disclosure are not limited thereto.

The cathode electrode 135 of the micro LED (ED) is exposed to partially remove the first optical layer 117a on the cathode electrode 135 for connection with the second electrode CE2 thereafter.

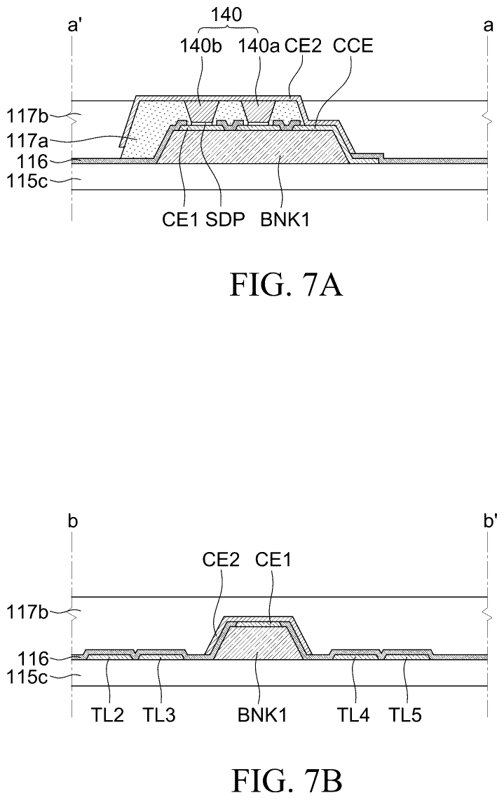

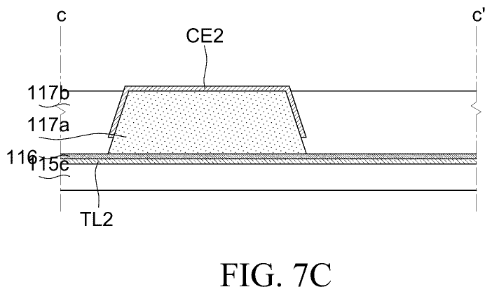

The second electrode CE2 is disposed on the micro LED (ED) and the first optical layer 117a of the active area AA. For example, the second electrode CE2 can be electrically connected to the connection electrode CCE disposed on the second bank BNK2. The connection electrode CCE can be electrically connected to the pixel driving circuit PD through a plurality of connection lines. Referring to FIG. 7A, the connection electrode CCE is formed on the third insulating layer 115c and extends along the side portion of the first bank BNK1 in the second direction Y to be formed above the first bank BNK1. The second electrode CE2 is disposed on the plurality of micro LEDs (ED) to be electrically connected to the cathode electrode 135 of the micro LED. For example, the second electrode CE2 can include a transparent conductive oxide, such as indium tin oxide (ITO) or indium zinc oxide (IZO), but the example embodiments of the present disclosure are not limited thereto.

A second optical layer 117b can be disposed on the passivation layer 116 on which the first optical layer 117a is not disposed. For example, the second optical layer 117b can be disposed so as to enclose the first optical layer 117a. For example, the second optical layer 117b can be formed on a side surface of the first optical layer 117a. For example, the second optical layer 117b can be disposed in an area between the plurality of pixels PX. However, the example embodiments of the present disclosure are not limited thereto. For example, the second optical layer 117b can be a diffusion layer, a diffusion window, or a window diffusion layer, but the example embodiments of the present disclosure are not limited thereto.

Referring to FIG. 6, the third optical layer 117c can be disposed on the second electrode CE2. The third optical layer 117c can be disposed so as to overlap the plurality of micro LEDs (ED) and the first optical layer 117a. The third optical layer 117c is disposed above the second electrode CE2 and the plurality of micro LEDs (ED) to improve a mura which can occur in a part of the plurality of micro LEDs (ED). Further, light emitted from the plurality of micro LEDs (ED) is uniformly dispersed by the third optical layer 117c to be extracted to the outside of the display device 1000 so that the luminance uniformity of the display device 1000 can be improved.

The third optical layer 117c is configured by an organic insulating material in which micro particles are dispersed, but the example embodiments of the present disclosure are not limited thereto. For example, the third optical layer 117c can be configured by siloxane in which micro metal particles, such as titanium dioxide (TiO₂) particles, are dispersed, but the example embodiments of the present disclosure are not limited thereto. For example, the third optical layer 117c is configured by the same material as the first optical layer 117a, but the example embodiments of the present disclosure are not limited thereto.

Referring to FIG. 4, in the active area AA, a black matrix BM can be disposed on the second electrode CE2, the first optical layer 117a, the second optical layer 117b, and the third optical layer 117c.

The black matrix BM is configured to cover the active area AA to reduce color mixture and external light reflection of light of the plurality of sub pixels.

For example, the black matrix BM can be configured by an opaque material, but the example embodiments of the present disclosure are not limited thereto. For example, the black matrix BM can be configured by an organic insulating material to which black pigment or black dye is added, but the example embodiments of the present disclosure are not limited thereto.

In the active area AA, a cover layer 118 can be disposed on the black matrix BM. The cover layer 118 can protect configurations below the cover layer 118. For example, the cover layer 118 can be configured by an organic insulating material, but the example embodiments of the present disclosure are not limited thereto. For example, the cover layer 118 can be configured by a photo resist, polyimide (PI), or photo acrylic-based material, but the example embodiments of the present disclosure are not limited thereto. For example, the cover layer 118 can be an over coating layer or an insulating layer, but the example embodiments of the present disclosure are not limited thereto.

The cover layer 118 is disposed to be thicker than the adhesive layer 112, the first protection layer 113a, the third protection layer 114, the first insulating layer 115a disposed in the bending area BA so as to protect the micro LED (ED) of the active area AA and the electrodes. When the cover layer 118 overflows to the bending area BA, a total thickness of layers disposed in the bending area BA is increased so that a bending defect can occur.

The polarization layer 293 can be disposed on the cover layer 118 by means of the first adhesive layer 291. A cover member 200 can be disposed on the polarization layer 293 by means of the second adhesive layer 295. For example, the first adhesive layer 291 and the second adhesive layer 295 can include an optically clear adhesive (OCA), an optically clear resin (OCR), or a pressure sensitive adhesive (PSA), but the example embodiments of the present disclosure are not limited thereto.

FIGS. 5 to 9B are plan views and cross-sectional views of a display device according to an example embodiment of the present disclosure.

For example, FIG. 5 is an enlarged plan view of an active area including a plurality of pixels.

Referring to FIG. 5, a plurality of signal lines TL, a plurality of communication lines NL, a plurality of first electrodes CE1, a plurality of connection electrodes CCE, a plurality of banks BNK, a plurality of micro LEDs (ED), and a second electrode CE2 are illustrated, but the example embodiments of the present disclosure are not limited thereto.

A plurality of pixels PX which is configured by a plurality of sub pixels can be disposed in the active area AA. Each of the plurality of sub pixels includes a micro LED (ED) and independently emits light. The plurality of sub pixels is formed in a matrix while forming a plurality of rows and a plurality of columns and the row direction is the first direction X and the column direction can be the second direction Y.

Each of the plurality of pixels PX can include one or more first sub pixels SP1, one or more second sub pixels SP2, and one or more third sub pixels SP3. For example, one pixel PX can include one pair of first sub pixels SP1, one pair of second sub pixels SP2, and one pair of third sub pixels SP3. One pair of first sub pixels SP1 can be configured by a 1-1-th sub pixel SP1a and a 1-2-th sub pixel SP1b. One pair of second sub pixels SP2 can be configured by a 2-1-th sub pixel SP2a and a 2-2-th sub pixel SP2b. One pair of third sub pixels SP3 can be configured by a 3-1-th sub pixel SP3a and a 3-2-th sub pixel SP3b. For example, one pixel PX can include a 1-1-th sub pixel SP1a and a 1-2-th sub pixel SP1b, a 2-1-th sub pixel SP2a and a 2-2-th sub pixel SP2b, and a 3-1-th sub pixel SP3a and a 3-2-th sub pixel SP3b, but the example embodiments of the present disclosure are not limited thereto.

In one pair of the 1-1-th sub pixel SP1a and the 1-2-th sub pixel SP1b of the first sub pixel SP1, a 1-1-th micro LED 130a and a 1-2-th micro LED 130b can be disposed, but the example embodiments of the present disclosure are not limited thereto.

In one pair of the 2-1-th sub pixel SP2a and the 2-2-th sub pixel SP2b of the second sub pixel SP2, a 2-1-th micro LED 140a and a 2-2-th micro LED 140b can be disposed, but the example embodiments of the present disclosure are not limited thereto.

In one pair of the 3-1-th sub pixel SP3a and the 3-2-th sub pixel SP3b of the third sub pixel SP3, a 3-1-th micro LED 150a and a 3-2-th micro LED 150b are disposed, but the example embodiments of the present disclosure are not limited thereto.

The plurality of sub pixels which forms one pixel PX can be disposed in various ways. For example, in one pixel PX, one pair of first sub pixels SP1 is disposed in the same column, one pair of second sub pixels SP2 is disposed in the same column, and one pair of third sub pixels SP3 can be disposed in the same column. The first sub pixels SP1, the second sub pixels SP2, and the third sub pixels SP3 can be disposed in the same row. The row direction can be the first direction X and the column direction can be the second direction Y. The number and a placement of the plurality of sub pixels which configures one pixel PX are illustrative, but the example embodiments of the present disclosure are not limited thereto.

The plurality of signal lines TL can be disposed in an area between the plurality of sub pixels. The plurality of signal lines TL can extend in the column direction between the plurality of sub pixels. The plurality of signal lines TL can be wiring lines which transmit an anode voltage from the pixel driving circuit PD to the plurality of sub pixels. For example, the plurality of signal lines TL can be electrically connected to the plurality of pixel driving circuits PD and the first electrodes CE1 of the plurality of sub pixels. The anode voltage output from the pixel driving circuit PD can be transmitted to the first electrode CE1 of the plurality of sub pixels through the plurality of signal lines TL. For example, the first electrode CE1 can be an electrode which is electrically connected to the anode electrode 134 of the micro LED (ED). Therefore, the anode voltage from the signal line TL can be transmitted to the anode electrode 134 of the micro LED (ED) through the first electrode CE1.

The plurality of signal lines TL can include a first signal line TL1, a second signal line TL2, a third signal line TL3, a fourth signal line TL4, a fifth signal line TL5, and a sixth signal line TL6. The first signal line TL1 and the second signal line TL2 can be electrically connected to one pair of first sub pixels SP1, respectively. The third signal line TL3 and the fourth signal line TL4 can be electrically connected to one pair of second sub pixels SP2, respectively. The fifth signal line TL5 and the sixth signal line TL6 can be electrically connected to one pair of third sub pixels SP3, respectively.

The first signal line TL1 is disposed on one of one pair of first sub pixels SP1 and the second signal line TL2 can be disposed on the other one of one pair of first sub pixels SP1. The first signal line TL1 is electrically connected to one first sub pixel SP1, between one pair of first sub pixels SP1, for example, to a first electrode CE1 of the 1-1-th sub pixel SP1a. The second signal line TL2 can be electrically connected to the other first sub pixel SP1, between one pair of first sub pixels SP1, for example, to a first electrode CE1 of the 1-2-th sub pixel SP1b.

The third signal line TL3 is disposed on one of one pair of second sub pixels SP2 and the fourth signal line TL4 can be disposed on the other one of one pair of second sub pixels SP2. For example, the third signal line TL3 can be disposed to be adjacent to the second signal line TL2. The third signal line TL3 can be electrically connected to one second sub pixel SP2, between one pair of second sub pixels SP2, for example, to a first electrode CE1 of the 2-1-th sub pixel SP2a. The fourth signal line TL4 can be electrically connected to the other second sub pixel SP2, between one pair of second sub pixels SP2, for example, to a first electrode CE1 of the 2-2-th sub pixel SP2b.

The fifth signal line TL5 is disposed on one of one pair of third sub pixels SP3 and the sixth signal line TL6 can be disposed on the other one of one pair of third sub pixels SP3. For example, the fifth signal line TL5 can be disposed to be adjacent to the fourth signal line TL4. The sixth signal line TL6 can be disposed to be adjacent to the first signal line TL1 connected to the adjacent pixel PX. The fifth signal line TL5 can be electrically connected to one third sub pixel SP3, between one pair of third sub pixels SP3, for example, to a first electrode CE1 of the 3-1-th sub pixel SP3a. The sixth signal line TL6 can be electrically connected to the other third sub pixel SP3, between one pair of third sub pixels SP3, for example, to a first electrode CE1 of the 3-2-th sub pixel SP3b.

The plurality of signal lines TL can be formed of a conductive material. For example, the plurality of signal lines TL is configured by a single layer or multi-layered structure of a conductive material, such as titanium (Ti), aluminum (Al), copper (Cu), molybdenum (Mo), nickel (Ni), chrome (Cr), indium tin oxide (ITO), indium zinc oxide (IZO), indium gallium zinc oxide (IGZO). However, the example embodiments of the present disclosure are not limited thereto.

The plurality of communication lines NL can be disposed in an area between the plurality of pixels PX. The plurality of communication lines NL can be disposed to extend in the first direction X in an area between the plurality of pixels PX. The plurality of communication lines NL is disposed in the area between the plurality of second electrodes CE2 and may not overlap the plurality of second electrodes CE2. For example, the plurality of communication lines NL can be wiring lines used for short distance communication, such as near field communication (NFC). The plurality of communication lines NL can serve as antennas. For example, the plurality of communication lines NL can be a plurality of connection lines, but the example embodiments of the present disclosure are not limited thereto.

According to aspects of the present disclosure, a bank BNK can be disposed in each of the plurality of sub pixels. The plurality of banks BNK can be structures in which the plurality of micro LEDs (ED) is seated. The plurality of banks BNK can guide a position of the plurality of micro LEDs (ED) during a transfer process of transferring the plurality of micro LEDs (ED) to the display device 1000. The plurality of micro LEDs (ED) can be transferred onto the plurality of banks BNK in the transfer process of the plurality of micro LEDs (ED). The plurality of banks BNK can be a bank pattern or a structure, but the example embodiments of the present disclosure are not limited thereto.

The plurality of banks BNK can include a first bank BNK1 and a second bank BNK2. The first bank BNK1 can be disposed in the second sub pixel SP2 and the second bank BNK2 is disposed in the first sub pixel SP1 and the third sub pixel SP3. The second bank BNK2 of the first sub pixel SP1, the first bank BNK1 of the second sub pixel SP2, and the second bank BNK2 of the third sub pixel SP3 can be disposed to be spaced apart from each other. For example, the second bank BNK2 of the first sub pixel SP1, the first bank BNK1 of the second sub pixel SP2, and the second bank BNK2 of the third sub pixel SP3 can be configured to be separated from each other.

At this time, a width of the first bank BNK1 in the second direction Y can be larger than a width of the second bank BNK2 in the second direction Y.

Therefore, when different types of micro LEDs (ED) are transferred, the first sub pixel SP1, the second sub pixel SP2, and the third sub pixel SP3 can be easily identified.

For example, the first bank BNK1 and the second bank BNK2 can be formed of an organic insulating material. The first bank BNK1 and the second bank BNK2 can be formed as a single layer or a double layer of an organic insulating material. For example, the plurality of banks BNK can be configured by a photo resist, polyimide (PI), or acrylic-based material, but the example embodiments of the present disclosure are not limited thereto.

The first electrode CE1 can be disposed in each of the plurality of sub pixels. The first electrode CE1 can be disposed on the first bank BNK1 and the second bank BNK2. For example, each of the first electrodes CE1 can be disposed on top surfaces and one side surfaces of the first bank BNK1 and the second bank BNK2.

At least a part of the first electrode CE1 extends to the outside of the first bank BNK1 and the second bank BNK2 to be electrically connected to a signal line TL which is the most adjacent to the first electrode CE1. For example, a part of the first electrode CE1 of the 1-1-th sub pixel SP1a extends to one area of the 1-1-th sub pixel SP1a to be electrically connected to the first signal line TL1. A part of the first electrode CE1 of the 1-2-th sub pixel SP1b extends to the other area of the 1-2-th sub pixel SP1b to be electrically connected to the second signal line TL2.

The first electrode CE1 is electrically connected to the anode electrode 134 of the micro LED (ED) and can transmit an anode voltage from the pixel driving circuit PD to the micro LED (ED) of each of the plurality of sub pixels through the signal line TL. Different voltages can be applied to the first electrodes CE1 of the plurality of sub pixels depending on the image to be displayed. For example, different voltages can be applied to the first electrodes CE1 of the plurality of sub pixels. Therefore, the first electrode CE1 can be a pixel electrode, but the example embodiments of the present disclosure are not limited thereto.

At least one connection electrode CCE can be disposed in every pixel PX. The connection electrode CCE can be disposed above the third insulating layer 115c and on a top surface of the first bank BNK1, and the other side surface in which the first electrode CE1 is not formed. The connection electrode CCE can be electrically connected to lower wiring lines and the pixel driving circuit PD at the outside of the first bank BNK1. The first bank BNK1 in which the connection electrode CCE is disposed includes an area in which the connection electrode CCE is to be disposed so that the first bank BNK1 in which the connection electrode CCE is disposed is formed to have a larger width than the second bank BNK2 in which the connection electrode CCE is not disposed.

The connection electrode CCE can be electrically connected to the cathode electrode 135 of the micro LED (ED) and can transmit a cathode voltage from the pixel driving circuit PD to the micro LED (ED) of each of the plurality of sub pixels through the connection line.

The plurality of micro LEDs (ED) can include a first micro LED 130, a second micro LED 140, and a third micro LED 150. The first micro LED 130 can be disposed in the first sub pixel SP1. The second micro LED 140 can be disposed in the second sub pixel SP2. The third micro LED 150 can be disposed in the third sub pixel SP3. For example, any one of the first micro LED 130, the second micro LED 140, and the third micro LED 150 is a red micro LED, another is a green micro LED, and the third is a blue micro LED, but the example embodiments of the present disclosure are not limited thereto. Therefore, red light, green light, and blue light emitted from the plurality of micro LEDs (ED) are combined to implement various color light including white. The types of the plurality of micro LEDs (ED) are illustrative, but the example embodiments of the present disclosure are not limited thereto.

The second electrode CE2 can be disposed in each of the plurality of sub pixels. The second electrode CE2 can be disposed on the micro LED (ED). The second electrode CE2 can be continuously connected to the plurality of pixels PX. The second electrode CE2 can be electrically connected to the pixel driving circuit PD through the plurality of connection electrodes CCE.

For example, the second electrode CE2 is electrically connected to the cathode electrode 135 of the micro LED (ED) to transmit a cathode voltage from the pixel driving circuit PD to the micro LED (ED). The same cathode voltage can be applied to the second electrodes CE2 of the plurality of sub pixels. For example, the same voltage is applied to the second electrode CE2 of each of the plurality of sub pixels and the cathode electrode 135 of the micro LED (ED). Therefore, the second electrode CE2 can be a common electrode, but the example embodiments of the present disclosure are not limited thereto.

At least some of the plurality of sub pixel can share the second electrode CE2. At least some of the second electrodes CE2 of the plurality of sub pixels can be electrically connected to each other. As the same voltage is applied to the second electrode CE2, the second electrodes CE2 of at least some of sub pixels can be used to be shared. For example, the second electrodes CE2 of at least some pixels PX, among the plurality of pixels PX disposed in the same first direction X, can be connected to each other. For example, one second electrode CE2 can be disposed in the plurality of pixels PX. One second electrode CE2 can be disposed in every n sub pixels.

For example, some of the second electrodes CE2 of the plurality of sub pixels can be disposed to be spaced apart or separated from each other. For example, a second electrode CE2 connected to pixels PX in a n-th row and a second electrode CE2 connected to pixels PX in a n+1-th row can be disposed to be spaced apart or separated from each other. For example, the plurality of second electrodes CE2 can be disposed to be spaced apart from each other with the plurality of communication lines NL extending in the first direction X which is a row direction therebetween.

The plurality of second electrodes CE2 is configured by a transparent conductive material so that light emitted from the micro LED (ED) travels toward the top of the second electrode CE2. For example, the second electrode CE2 can be configured by a transparent conductive material, such as indium tin oxide (ITO), indium zinc oxide (IZO), indium gallium zinc oxide (IGZO), but the example embodiments of the present disclosure are not limited thereto.

The connection electrode CCE can be disposed on the first bank BNK1. For example, the first bank BNK1 can be formed to have a larger width than that of the second bank BNK2 in the second direction Y. At least one micro LED (ED) is disposed on the first bank BNK1 and the connection electrode CCE can be disposed in an area above the first bank BNK1 in the second direction Y.

The connection electrode CCE is disposed to extend to the other side surface of the first bank BNK1 and can be electrically connected to connection lines therebelow.

Each of the second electrodes CE2 can overlap at least one connection electrode CCE. For example, one second electrode CE2 can overlap the plurality of connection electrodes CCE.

For example, the plurality of connection electrodes CCE can be electrically connected to the plurality of second electrodes CE2. The plurality of connection electrodes CCE is disposed between the substrate 110 and the plurality of second electrodes CE2 to transmit a cathode voltage from the pixel driving circuit PD to the second electrode CE2.

In order to be connected to the connection electrode CCE, the second electrode CE2 can be formed to protrude to the second direction Y. The more the second electrode CE2 overlaps the signal lines TL therebelow, the worse the performance of the display device due to the parasitic capacitance generated between the second electrode CE2 and the signal lines TL. Therefore, only in the place where the connection electrode CCE is disposed, the second electrode CE2 can be formed to protrude to the second direction Y.

When a micro LED is used as the micro LED (ED), a plurality of micro LEDs is formed on a wafer and the micro LED is transferred onto the substrate 110 of the display device 1000 to manufacture the display device 1000. However, during the process of transferring the plurality of micro LEDs (ED) having a micro size from the wafer to the substrate 110, various defects can be caused. For example, in some sub pixel, a non-transfer defect in which the micro LED (ED) is not transferred can occur and in the other sub pixel, a defect that the micro LED (ED) is transferred in a wrong position can occur due to the alignment error. Further, even though the transfer process is normally performed, the transferred micro LED (ED) can be defective. Accordingly, in consideration of the defects during the transfer process of the plurality of micro LEDs (ED), a plurality of micro LEDs (ED) which emits the same color light can be transferred into one sub pixel. A lighting test for the plurality of micro LEDs (ED) is performed and only one micro LED (ED) which is finally determined to be normal can be used.

For example, the 1-1-th micro LED 130a and the 1-2-th micro LED 130b are transferred to one pixel PX together and defects thereof can be tested. If both the 1-1-th micro LED 130a and the 1-2-th micro LED 130b are determined to be normal, only the 1-1-th micro LED 130a is used, but the 1-2-th micro LED 130b may not be used. Accordingly, even though the plurality of micro LEDs (ED) which emits the same color light is transferred into one pixel PX, finally, only one micro LED (ED) is used.

Therefore, any one of one pair of micro LEDs (ED) is a main (or primary) micro LED (ED) and the other micro LED (ED) can be a redundancy micro LED (ED). The redundancy micro LED (ED) can be an extra micro LED (ED) which is transferred to prepare for a defect of the main micro LED (ED). When the main micro LED (ED) is defective, the redundancy micro LED (ED) can be used instead. Accordingly, the main micro LED (ED) and the redundancy micro LED (ED) are transferred together to one pixel PX so that the degradation of the display quality due to the defects of the main micro LED (ED) and the redundancy micro LED (ED) can be minimized.

Finally, the black matrix BM is formed in an active area AA and a non-active area NA excluding an emission area of the micro LED used in each sub pixel, between the redundancy micro LED (ED) or the main micro LED (ED), to suppress light emitted from a micro LED which is not used in each sub pixel from being emitted upwardly.

FIG. 6 is an enlarged view of a light emitting diode according to an example embodiment of the present disclosure.

Referring to FIG. 6, the first micro LED 130 which is a light emitting diode can include an anode electrode 134, a first semiconductor layer 131, an active layer 132, a second semiconductor layer 133, a cathode electrode 135, and an encapsulation film 136, but the example embodiments of the present disclosure are not limited thereto. For example, the encapsulation film 136 may not be included in the first micro LED 130.

For example, one of the first semiconductor layer 131 and the second semiconductor layer 133 can be implemented by a compound semiconductor, such as a III-V group or a II-VI group and can be doped with an impurity (or dopant). For example, one of the first semiconductor layer 131 and the second semiconductor layer 133 is an n-type impurity doped semiconductor layer and the other one is a p-type impurity doped semiconductor layer, but the example embodiments of the present disclosure are not limited thereto. For example, one or more of the first semiconductor layer 131 and the second semiconductor layer 133 can be a layer in which n-type or p-type impurity is doped on a material, such as gallium nitride (GaN), gallium phosphide (GaP), gallium arsenide phosphide (GaAsP), aluminum gallium indium phosphide (AlGaInP), indium aluminum phosphide (InAlP), aluminum gallium nitride (AlGaN), aluminum indium nitride (AlInN), aluminum indium gallium nitride (AlInGaN), aluminum gallium arsenide (AlGaAs), or gallium arsenide (GaAs). However, the example embodiments of the present disclosure are not limited thereto.

The active layer 132 can be disposed between the first semiconductor layer 131 and the second semiconductor layer 133. The active layer 132 is supplied with holes and electrons from the first semiconductor layer 131 and the second semiconductor layer 133 to emit light. For example, the active layer 132 can be configured by one of a single well structure, a multi-well structure, a signal quantum well structure, a multi-quantum well (MQC) structure, a quantum dot structure, and a quantum line structure, but the example embodiments of the present disclosure are not limited thereto. For example, the active layer 132 can be configured by indium gallium nitride (InGaN) or gallium nitride (GaN), but the example embodiments of the present disclosure are not limited thereto.

The anode electrode 134 can be disposed below the first semiconductor layer 131. The anode electrode 134 is formed of a conductive material which is eutectically bondable to the solder pattern SDP. For example, the anode electrode 134 can be configured by gold (Au), tin (Sn), tungsten (W), silicon (Si), silver (Ag), titanium (Ti), iridium (Ir), chromium (Cr), indium (In), zinc (Zn), lead (Pb), nickel (Ni), platinum (Pt), and copper (Cu), or an alloy thereof, but the example embodiments of the present disclosure are not limited thereto.

The cathode electrode 135 can be disposed on the second semiconductor layer 133. For example, the cathode electrode 135 can electrically connect the second semiconductor layer 133 and the second electrode CE2. A cathode voltage output from the pixel driving circuit PD can be applied to the second semiconductor layer 133 through the connection electrode CCE, the second electrode CE2, and the cathode electrode 135. The cathode electrode 135 can be configured by a transparent conductive material to allow light emitted from the micro LED (ED) to be directed to the top of the micro LED (ED), but the example embodiments of the present disclosure are not limited thereto. For example, the cathode electrode 135 can be configured by a material, such as indium tin oxide (ITO), indium zinc oxide (IZO), indium gallium zinc oxide (IGZO), but the example embodiments of the present disclosure are not limited thereto.

The encapsulation film 136 can be disposed in at least a part of the first semiconductor layer 131, the active layer 132, the second semiconductor layer 133, the anode electrode 134, and the cathode electrode 135. For example, the encapsulation film 136 can enclose at least a part of the first semiconductor layer 131, the active layer 132, the second semiconductor layer 133, the anode electrode 134, and the cathode electrode 135.

For example, the encapsulation film 136 can protect the first semiconductor layer 131, the active layer 132, and the second semiconductor layer 133. For example, the encapsulation film 136 can be disposed on a side surface of the first semiconductor layer 131, a side surface of the active layer 132, and a side surface of the second semiconductor layer 133. For example, the encapsulation film 136 can be formed of an insulating material, such as silicon nitride (SiNx) or silicon oxide (SiOx), but the example embodiments of the present disclosure are not limited thereto.

FIG. 7A is a cross-sectional view taken along line a-a′ of FIG. 5 according to an example embodiment of the present disclosure.

Referring to FIG. 7A, the second micro LED 140 is disposed on the first bank BNK1 and the first optical layer 117a is disposed so as to enclose a part of the first bank BNK1 and the second micro LED 140, but the example embodiments of the present disclosure are not limited thereto.

Next, a part of the first optical layer 117a can be removed using an etching process to expose the cathode electrode 135 of the second micro LED 140, but the example embodiments of the present disclosure are not limited thereto.

The second electrode CE2 is formed on the first optical layer 117a and can be electrically connected to the cathode electrode 135 of the second micro LED 140 and the connection electrode CCE on the first bank BNK1. The second electrode CE2 can be disposed to extend along the side portion of the first optical layer 117a. The connection electrode CCE is formed to extend along the top and one side surface of the first bank BNK1 and the second electrode CE2 can be in contact with the connection electrode CCE which extends along one side surface of the first bank BNK1, but the example embodiments of the present disclosure are not limited thereto.

The second electrode CE2 is formed such that a width of the second direction Y intersecting the first direction X is larger than a width of the first bank BNK1 and the second bank BNK2 of the second direction, but the example embodiments of the present disclosure are not limited thereto.

The passivation layer 116 disposed above the connection electrode CCE can be partially removed in a contact portion of the second electrode CE2 and the connection electrode CCE, but the example embodiments of the present disclosure are not limited thereto.

The second optical layer 117b disposed on the passivation layer 116 is disposed on the side surface of the first optical layer 117a and the second electrode CE2 can be disposed between the first optical layer 117a and the second optical layer 117b.

FIG. 7B is a cross-sectional view taken along line b-b′ of FIG. 5 according to an example embodiment of the present disclosure.

Referring to FIG. 7B, in an area in which the first optical layer 117a is not disposed, the second electrode CE2 and first electrode CE1 can be connected on the first bank BNK1, but the example embodiments of the present disclosure are not limited thereto.

The second electrode CE2 can be disposed to extend along the side surface of the first bank BNK1.

FIG. 7C is a cross-sectional view taken along line c-c′ of FIG. 5 according to an example embodiment of the present disclosure.

Referring to FIG. 7C, the second electrode CE2 is disposed on the top and the side surface of the first optical layer 117a. The second optical layer 117b is formed above the passivation layer 116 and the side surface of the first optical layer 117a. The second electrode CE2 can be disposed between the first optical layer 117a and the second optical layer 117b, but the example embodiments of the present disclosure are not limited thereto.

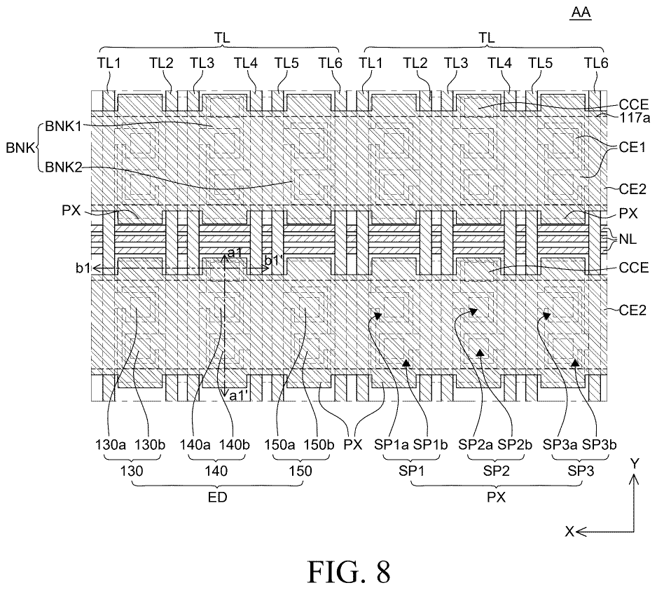

FIG. 8 is a plan view of a display device according to another example embodiment of the present disclosure. Components which are the same as or correspond to components of FIG. 5, among components illustrated in FIG. 8, will not be described or simplified.

The larger the width of the second electrode CE2, the lower the resistance of the second electrode CE2. However, the more the overlapping portion of the second electrode CE2 and the signal line TL and the communication line NL therebelow, the larger the parasitic capacitance. Therefore, in a position where the signal line TL and the communication line NL are not formed below the second electrode CE2, the width of the second electrode CE2 is increased to the maximum.

Referring to FIG. 8, the second electrode CE2 extends in the first direction X to continuously overlap the plurality of pixels and can include a plurality of protrusions extending in the second direction Y in each sub pixel SP. The width of the second electrode in the second direction Y is equal in every sub pixel SP.

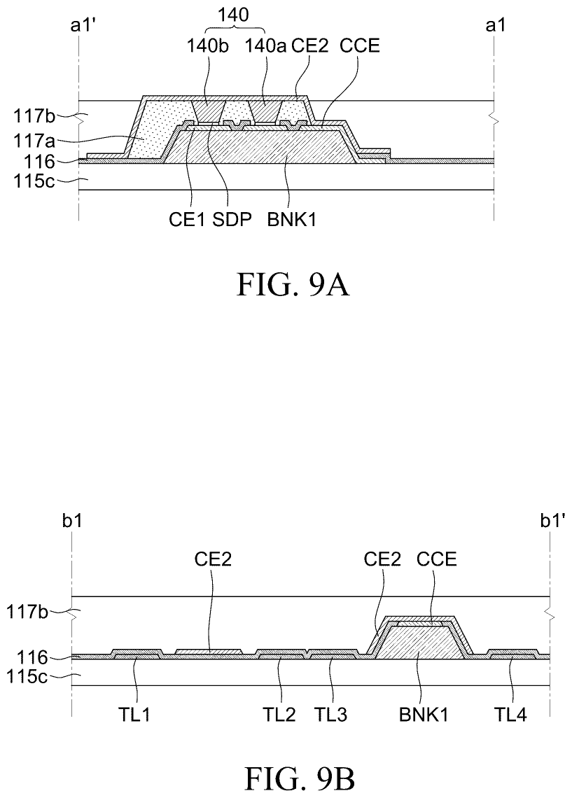

FIG. 9A is a cross-sectional view taken along line a1-a1′ of FIG. 8 according to another example embodiment of the present disclosure.

Referring to FIG. 9A, the second electrode CE2 is formed on the first optical layer 117a and can be electrically connected to the cathode electrode 135 of the second micro LED 140 and the connection electrode CCE on the first bank BNK1. The second electrode CE2 can be disposed to extend along the side surface portion of the first optical layer 117a. The connection electrode CCE is formed to extend along the top and one side surface of the first bank BNK1 and the second electrode CE2 can be in contact with the connection electrode CCE which extends along one side surface of the first bank BNK1, but the example embodiments of the present disclosure are not limited thereto.

The passivation layer 116 disposed above the connection electrode CCE can be partially removed in a contact portion of the second electrode CE2 and the connection electrode CCE, but the example embodiments of the present disclosure are not limited thereto.

The second electrode CE2 is formed to be wider than the width of the first optical layer 117a and the first bank BNK1 of the second direction Y to extend to an upper portion of the passivation layer 116, but the example embodiments of the present disclosure are not limited thereto.

FIG. 9B is a cross-sectional view taken along line b1-b1′ of FIG. 8 according to another example embodiment of the present disclosure.

Referring to FIG. 9B, in an area of the sub pixel SP in which the first optical layer 117a is not disposed, but the first bank BNK1 is disposed, the second electrode CE2 and the connection electrode CCE can be connected on the first bank BNK1.

The second electrode CE2 is formed to have the same width in the second direction Y in every sub pixel SP. In the area of the sub pixel SP in which the second bank BNK2 is disposed, the second electrode CE2 can be formed on the passivation layer 116 between the signal lines TL.

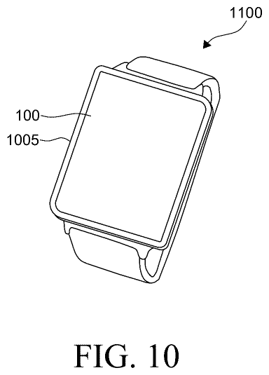

FIG. 10 is an example of a device to which a display device according to example embodiments of the present disclosure is applied and referring to FIG. 10, an electronic device can be included in a wearable device 1100. The display device 1000 according to the example embodiments of the present disclosure can be applied to the wearable device 1100, a navigation device, a mobile device, a notebook, a monitor, or a TV, but the example embodiments of the present disclosure are not limited thereto.

As an example, such an electronic device can include a case unit 1005, the display panel 100, and the display device 1000.

A display device and a method of fabricating the display device according to aspects of the present disclosure can be discussed as follows.

According to an embodiment of the present disclosure, a display device includes a substrate, an active area having a plurality of pixels on the substrate, a plurality of insulating layers disposed in the active area, a first bank and a second bank disposed on the plurality of insulating layers, a first electrode disposed on the first bank and the second bank, at least one micro LED disposed on the first bank and the second bank, a first optical layer enclosing the first bank, the second bank, and a part of the at least one micro LED, a connection electrode disposed on the first bank, and a second electrode disposed on a top surface and a side surface of the first optical layer and connected to the connection electrode.

Each of the first bank and the second bank can have a first width in a first direction and a second width in a second direction which intersects the first direction and the second width of the first bank can be larger than the second width of the second bank.

The first optical layer and the second electrode can be disposed to extend in the first direction in the active area.

The width of the second electrode in the second direction can be larger than the second width of the first bank and the second width of the second bank.

The first optical layer and the second electrode can be continuously disposed in the plurality of pixels.

The connection electrode can be disposed to extend along one side surface of the first bank and the second electrode can be in contact with the connection electrode which extends along one side surface of the first bank.

The display device can further include a second optical layer which is disposed on the substrate and is disposed on a side surface of the first optical layer, the second electrode is disposed between the first optical layer and the second optical layer.

The display device can further include a third optical layer disposed on the second electrode.

The display device can further include a pixel driving circuit disposed on the substrate, the connection electrode is electrically connected to the pixel driving circuit.

Each of the plurality of pixels can include a sub pixel and the first bank or the second bank is disposed in the sub pixel.

A width of the second electrode of the second direction can be equal in every sub pixel.

According to an embodiment of the present disclosure, a method of fabricating a display device includes forming a pixel driving circuit on a substrate, forming a plurality of insulating layers on the pixel driving circuit, forming a first bank and a second bank on the plurality of insulating layers, forming a connection electrode in the first bank, placing at least one micro LED on the first bank and the second bank, forming a first optical layer which encloses the first bank, the second bank, and the at least one micro LED, and placing a second electrode on the first optical layer, wherein the second electrode is connected to the connection electrode on the first bank and the connection electrode and the second electrode is formed to extend along a side surface of the first bank.

The second electrode can be formed to extend along a side surface of the first optical layer.

The method of fabricating the display device can further include forming a second optical layer on a side surface of the first optical layer, on the substrate, the second electrode is disposed between a side surface of the first optical layer and the second optical layer.

The method of fabricating the display device can further include forming a third optical layer on the second electrode.

The first optical layer and the second electrode can extend in the first direction to be disposed in the plurality of pixels.

A width of the first bank of the second direction which intersects the first direction can be larger than a width of the second bank in the second direction.

The second electrode can be formed to protrude to the second direction which intersects the first direction in a sub pixel disposed in each of the plurality of pixels.

Although the example embodiments of the present disclosure have been described in detail with reference to the accompanying drawings, the present disclosure is not limited thereto and can be embodied in many different forms without departing from the technical concept of the present disclosure. Therefore, the example embodiments of the present disclosure are provided for illustrative purposes only but not intended to limit the technical concept of the present disclosure. The scope of the technical concept of the present disclosure is not limited thereto. Therefore, it should be understood that the above-described example embodiments are illustrative in all aspects and do not limit the present disclosure. All the technical concepts in the equivalent scope of the present disclosure should be construed as falling within the scope of the present disclosure.

What is claimed is:

1. A display device, comprising:
a substrate;
an active area having a plurality of pixels on the substrate;
a plurality of insulating layers disposed in the active area;
a first bank and a second bank disposed on the plurality of insulating layers;
a first electrode disposed on the first bank and the second bank;
at least one micro light emitting diode (LED) disposed on the first bank and the second bank;
a first optical layer enclosing the first bank, the second bank, and a part of the at least one micro LED;
a connection electrode disposed on the first bank; and
a second electrode disposed on a top surface and a side surface of the first optical layer and connected to the connection electrode.

2. The display device according to claim 1, wherein each of the first bank and the second bank has a first width in a first direction and a second width in a second direction which intersects the first direction, and
wherein the second width of the first bank is larger than the second width of the second bank.

3. The display device according to claim 2, wherein the second electrode is formed to protrude in the second direction only in a place where the connection electrode is disposed.

4. The display device according to claim 2, wherein the first optical layer and the second electrode are disposed to extend in the first direction in the active area.

5. The display device according to claim 4, wherein the width of the second electrode in the second direction is larger than the second width of the first bank and the second width of the second bank.

6. The display device according to claim 1, wherein the first optical layer and the second electrode are continuously disposed in the plurality of pixels.

7. The display device according to claim 1, wherein the connection electrode is disposed to extend along one side surface of the first bank, and the second electrode is in contact with the connection electrode extending along one side surface of the first bank.

8. The display device according to claim 1, further comprising:
a second optical layer disposed on the substrate and a side surface of the first optical layer,
wherein the second electrode is disposed between the first optical layer and the second optical layer.

9. The display device according to claim 1, further comprising:
a third optical layer disposed on the second electrode.

10. The display device according to claim 1, further comprising:
a pixel driving circuit disposed on the substrate,
wherein the connection electrode is electrically connected to the pixel driving circuit.

11. The display device according to claim 2, wherein each of the plurality of pixels includes a sub pixel, and the first bank or the second bank is disposed in the sub pixel.

12. The display device according to claim 11, wherein a width of the second electrode in the second direction is equal in every sub pixel.

13. A method of fabricating a display device, the method comprising:
forming a pixel driving circuit and a plurality of pixels on a substrate;
forming a plurality of insulating layers on the pixel driving circuit;
forming a first bank and a second bank on the plurality of insulating layers;
forming a connection electrode in the first bank;
placing at least one micro light emitting diode (LED) on the first bank and the second bank;
forming a first optical layer which encloses the first bank, the second bank, and the at least one micro LED; and
placing a second electrode on the first optical layer,
wherein the second electrode is connected to the connection electrode on the first bank, and the connection electrode and the second electrode are formed to extend along a side surface of the first bank.

14. The method of fabricating the display device according to claim 13, wherein the second electrode is formed to extend along a side surface of the first optical layer.

15. The method of fabricating the display device according to claim 14, further comprising:
forming a second optical layer on a side surface of the first optical layer, on the substrate,
wherein the second electrode is disposed between the side surface of the first optical layer and the second optical layer.

16. The method of fabricating the display device according to claim 13, further comprising:
forming a third optical layer on the second electrode.

17. The method of fabricating the display device according to claim 13, wherein the first optical layer and the second electrode extend in a first direction to be disposed in the plurality of pixels.

18. The method of fabricating the display device according to claim 17, wherein a width of the first bank in a second direction which intersects the first direction is larger than a width of the second bank in the second direction.

19. The method of fabricating the display device according to claim 17, wherein the second electrode is formed to protrude in a second direction which intersects the first direction in a sub pixel disposed in each of the plurality of pixels.
